(19) United States
(12) Patent Application Publication
(10) Pub. No.: US 2023/0283108 A1
(43) Pub. Date: Sep. 7, 2023

(54) CHARGING DEVICE AND ELECTRONIC DEVICE ASSEMBLY

(71) Applicant: GUANGDONG OPPO MOBILE TELECOMMUNICATIONS CORP., LTD., Dongguan (CN)

(72) Inventor: Zhongyu AN, Dongguan (CN)

(21) Appl. No.: 18/317,904

(22) Filed: May 15, 2023

Related U.S. Application Data
(63) Continuation of application No. PCT/CN2021/115709, filed on Aug. 31, 2021.

(30) Foreign Application Priority Data
Nov. 16, 2020 (CN) 202011281947.6

(51) Int. Cl. H02J 50/00; H02J 50/10; H02J 7/00; H05K 5/02

(52) U.S. Cl. CPC H02J 50/005; H02J 50/10; H02J 7/0044; H05K 5/0217; H05K 5/0247

(57) ABSTRACT

A charging device and an electronic device assembly are provided in the disclosure. The charging device has a horizontal state and a vertical state. The charging device may include a first housing, a second housing, a charging assembly, and a motor assembly. The first housing defines a first receiving space. The second housing is rotatably connected with the first housing and configured to hold an electronic device. The charging assembly is received in the second housing and configured to charge the electronic device. The motor assembly is received in the first receiving space and configured to drive the second housing to rotate relative to the first housing. The second housing has a first end and a second end opposite the first end. The second end is farther away from the first housing than the first end when the charging device is in the vertical state.

### CROSS-REFERENCE TO RELATED APPLICATIONS

The application is a continuation of International Application No. PCT/CN2021/115709, filed Aug. 31, 2021, which claims priority to Chinese Patent Application No. 202011281947.6, filed Nov. 16, 2020, the entire disclosures of which are incorporated herein by reference.

### TECHNICAL FIELD

This disclosure relates to the field of electronic product technology, and in particular, to a charging device and an electronic device assembly.

### BACKGROUND

With the continuous development and widespread use of electronic devices, the number of electronic devices is increasing. As a result, charging devices, as one of peripheral products of the electronic devices, are also receiving more and more attention.

### SUMMARY

In view of above, a charging device is provided in a first aspect of the disclosure. The charging device has a horizontal state and a vertical state. The charging device includes a first housing, a second housing, a charging assembly, and a motor assembly. The first housing defines a first receiving space. The second housing is rotatably connected with the first housing and configured to hold an electronic device. The charging assembly is received in the second housing and configured to charge the electronic device. The motor assembly is received in the first receiving space and configured to drive the second housing to rotate relative to the first housing. The second housing has a first end and a second end opposite the first end. The second end is farther away from the first housing than the first end when the charging device is in the vertical state. The motor assembly is connected with the second end. In the horizontal state, the second housing is parallel to the first housing. In the vertical state, the second housing is angled relative to the first housing.

An electronic device assembly is provided in a second aspect of the disclosure. The electronic device assembly includes an electronic device and the charging device provided in the first aspect of the disclosure. The electronic device includes an induction coil and a battery. The charging coil and the induction coil cooperate to charge the battery.

### BRIEF DESCRIPTION OF THE DRAWINGS

To describe technical solutions in implementations of the disclosure more clearly, the following introduces the accompanying drawings required for describing the implementations of the disclosure.

FIG. 1 is a schematic view of a charging device in a horizontal state in an implementation of the disclosure.

FIG. 2 is a schematic cross-sectional view of the charging device in FIG. 1, taken along line A-A.

FIG. 3 is a schematic view of a charging device in a vertical state in an implementation of the disclosure.

FIG. 4 is a schematic cross-sectional view of the charging device in FIG. 3, taken along line B-B.

FIG. 5 is a schematic perspective structural view of a motor assembly in an implementation of the disclosure.

FIG. 6 is an exploded view of the motor assembly in FIG. 5.

FIG. 7 is an exploded view of a charging device in an implementation of the disclosure.

FIG. 8 is an exploded view of a motor assembly and a support member in an implementation of the disclosure.

FIG. 9 is a schematic partial structural view of a motor assembly in another implementation of the disclosure.

FIG. 10 is an exploded view of the motor assembly in FIG. 9.

FIG. 11 is a schematic partial structural view of a motor assembly in yet another implementation of the disclosure.

FIG. 12 is an exploded view of the motor assembly in FIG. 11.

FIG. 13 is a schematic structural view of a motor assembly in yet another implementation of the disclosure.

FIG. 14 is a schematic cross-sectional view of the charging device in FIG. 1 in another implementation of the disclosure, taken along line A-A.

FIG. 15 is a schematic structural diagram of electronic parts of a charging device in an implementation of the disclosure.

FIG. 16 is a schematic structural diagram of electronic parts of a charging device in another implementation of the disclosure.

FIG. 17 is a schematic structural diagram of electronic parts of a charging device in yet another implementation of the disclosure.

FIG. 18 is a schematic structural diagram of electronic parts of a charging device in yet another implementation of the disclosure.

FIG. 19 is an exploded view of a charging assembly in an implementation of the disclosure.

FIG. 20 is a schematic structural view of an electronic device assembly in an implementation of the disclosure.

FIG. 21 is a schematic cross-sectional view of the electronic device assembly in FIG. 20, taken along line C-C.

### REFERENCE SIGNS

charging device—1, electronic device—2, electronic device assembly—3, induction coil—4, battery—5, first housing—10, first receiving space—100, bottom wall—11, side wall—12, second housing—20, second receiving space—200, first end—201, second end—202, protruding portion—21, sixth rotating portion—211, charging assembly—30, charging coil—31, heat dissipation support—32, holder—40, positioning recess—41, motor assembly—50, gear assembly—500, rack—501, motor—51, first rotating portion—511, second rotating portion—512, third rotating portion—513, fourth rotating portion—514, fifth rotating portion—515, slider—52, threaded hole—520, first sliding portion—5200, second sliding portion—5202, connecting portion—523, sliding block—5204, sliding groove—5205, first connecting rod—53, second connecting rod—54, lead screw—55, threads—550, bearing—551, support member —56, bottom plate—561, side plate—562, sliding space—563, guide rod—57, first through hole—571, second through hole—572, third through hole—573, elastic member—58, first magnetic member—591, second magnetic member—592, processor—60, communication component—61, distance sensor—62, speaker—63, first switch—64, second switch—65, rotating shaft—70.

### DETAILED DESCRIPTION

The following are preferred implementations of the disclosure, and it is noted that various improvements and modifications can be made without departing from the principle of the disclosure to those of ordinary skill in the art, and the improvement and the modification are also considered as the protection scope of the disclosure.

A charging device is provided in implementations of the disclosure. The charging device has a horizontal state and a vertical state. The charging device includes a first housing, a second housing, a charging assembly, and a motor assembly. The first housing defines a first receiving space. The second housing is rotatably connected with the first housing and configured to hold an electronic device. The charging assembly is received in the second housing and configured to charge the electronic device. The motor assembly is received in the first receiving space and configured to drive the second housing to rotate relative to the first housing. The second housing has a first end and a second end opposite the first end. The second end is farther away from the first housing than the first end when the charging device is in the vertical state. The motor assembly is connected with the second end. In the horizontal state, the second housing is parallel to the first housing. In the vertical state, the second housing is angled relative to the first housing.

The motor assembly may include a motor, a slider, a first connecting rod, and a second connecting rod. The motor is connected with the slider and configured to drive the slider to slide. The first connecting rod has one end rotatably connected with the slider and the other end rotatably connected with one end of the second connecting rod. The other end of the second connecting rod is connected with the second housing.

The other end of the second connecting rod is rotatably connected with the second housing.

The motor assembly may further include a lead screw. The lead screw has one end rotatably connected with the motor. The slider is sleeved on the lead screw. The slider is provided with a first sliding portion. The charging device may further include a second sliding portion connected with the first housing. The first sliding portion cooperates with the second sliding portion to enable the slider to slide under rotation of the lead screw driven by the motor.

The slider defines a threaded hole, and the slider is threadedly connected with the lead screw through the threaded hole.

The first housing may include a bottom wall and a side wall that is connected with and bent relative to a periphery of the bottom wall. The bottom wall and the side wall cooperate to define the first receiving space. The charging device may further include a support member connected with the bottom wall, and the second sliding portion is disposed on a side surface of the support member away from the bottom wall.

The slider may include a connecting portion and sliding blocks respectively protruding from opposite ends of the connecting portion. The connecting portion is sleeved on the lead screw. The support member defines sliding grooves on a side surface of the support member away from the bottom wall. The sliding blocks cooperate with the sliding grooves to slide the slider.

The motor assembly may further include a support member and a guide rod. The support member may include a bottom plate and side plates that are respectively connected with and bent relative to opposite ends of the bottom plate. The bottom plate and the side plates cooperate to define a sliding space. The slider is received in the sliding space. The side plate defines a first through hole, and the lead screw extends through the first through hole and the slider. The side plate defines a second through hole. The slider defines a third through hole. The guide rod is connected with the side plate and extends through the second through hole and the third through hole. The slider is slidable on the guide rod through the third through hole.

The motor assembly may further include an elastic member received in the sliding space and sleeved on the guide rod. The elastic member is disposed between the side plate and the slider. The elastic member abuts against the side plate and the slider and is in a compressed state when the charging device is in the horizontal state.

The motor assembly may further include a gear assembly and a rack. The gear assembly has one end rotatably connected with the motor and the other end meshed with the rack. The rack is connected with the slider, and the motor is configured to drive the gear assembly to rotate, the rack is configured to move with rotation of the gear assembly, and the slider is configured to slide with movement of the rack.

The slider is provided with a first rotating portion, the first connecting rod is provided with a second rotating portion at one end of the first connecting rod, and the first rotating portion cooperates with the second rotating portion to enable the slider to be rotatably connected with the one end of the first connecting rod.

The first connecting rod is provided with a third rotating portion at the other end, the second connecting rod is provided with a fourth rotating portion at one end, and the third rotating portion cooperates with the fourth rotating portion to enable the other end of the first connecting rod to be rotatably connected with the one end of the second connecting rod.

The second connecting rod is provided with a fifth rotating portion at the other end. The second housing is provided with a protruding portion on a side surface of the second housing close to the first housing. The protruding portion is provided with a sixth rotating portion. The fifth rotating portion cooperates with the sixth rotating portion to enable the other end of the second connecting rod to be rotatably connected with the second housing.

An axial dimension of the first connecting rod is larger than an axial dimension of the second connecting rod.

The first housing may include a bottom wall and a side wall that is connected with and bent relative to a periphery of the bottom wall. A holder is disposed on a side surface of at least part of the side wall away from the bottom wall. The at least part of the side wall is close to the first end. The holder and a side surface of the second housing away from the bottom wall cooperate to define a positioning recess when the charging device is in the vertical state. The positioning recess is configured to position the electronic device.

The charging device may further include a first magnetic member connected with the first housing and a second magnetic member connected with the second housing. The first magnetic member cooperates with the second magnetic member to generate repulsive force when the charging device switches to the vertical state from the horizontal state.

The charging device may further include a processor received in the first receiving space and electrically connected with the motor assembly. The processor is configured to send a first control signal to the motor assembly to start the motor assembly, and configured to send a second control signal to the motor assembly to stop the motor assembly.

The charging device may further include a distance sensor received in the first receiving space. The distance sensor is electrically connected with the processor and connected with the motor assembly. During operation of the motor assembly, the distance sensor is configured to send a distance signal to the processor, and the processor is further configured to obtain a rotation angle of the second housing according to the distance signal. The processor is further configured to determine whether the rotation angle of the second housing is greater than or equal to a preset angle, and the processor is further configured to send the second control signal to the motor assembly to stop the motor assembly in response to the rotation angle of the second housing being greater than or equal to the preset angle.

The charging device may further include a speaker received in the first receiving space and electrically connected with the processor. The processor is further configured to send an audio signal to the speaker to make the speaker sound when the processor sends the first control signal to the motor assembly. The processor is further configured to stop sending the audio signal to the speaker when the processor sends the second control signal to the motor assembly.

The charging device may further include a first switch and a second switch received in the first receiving space. Both the first switch and the second switch are electrically connected with the processor. The first switch is configured to send a vertical signal to the processor in response to pressing of the first switch, and the processor is further configured to send the first control signal to the motor assembly according to the vertical signal, the motor assembly is configured to drive the second housing to rotate in a first direction; and the second switch is configured to send a horizontal signal to the processor in response to pressing of the second switch. The processor is further configured to send a third control signal to the motor assembly according to the horizontal signal, the motor assembly is configured to drive the second housing to rotate in a second direction, where the first direction is opposite to the second direction.

The processor is further configured to obtain a pressing duration of the first switch according to the vertical signal and determine whether the pressing duration is less than a preset duration, and the processor is configured to send the second control signal to the motor assembly in response to the pressing duration being less than the preset duration and the rotation angle of the second housing being equal to the preset angle, or the processor is configured to send the second control signal to the motor assembly in response to the pressing duration being greater than or equal to the preset duration and removal of a touch force on the first switch.

The charging device may further include a communication component received in the first receiving space. The communication component is electrically connected with the processor and configured to receive a fourth control signal from a terminal device. The communication component is further configured to send the fourth control signal to the processor, and the processor is further configured to start or stop the motor assembly according to the fourth control signal.

The second housing defines a second receiving space. The charging device may further include the charging assembly received in the second receiving space. The charging assembly may include a charging coil and a heat dissipation support. The charging coil is disposed on the heat dissipation support and electrically connected with the processor, and the processor is further configured to send a charging signal to the charging coil to enable the charging coil to charge the electronic device.

An electronic device assembly is further provided in the implementations. The electronic device assembly includes an electronic device and the charging device provided in the above-mentioned implementations. The electronic device may include an induction coil and a battery. The charging coil and the induction coil cooperate to charge the battery.

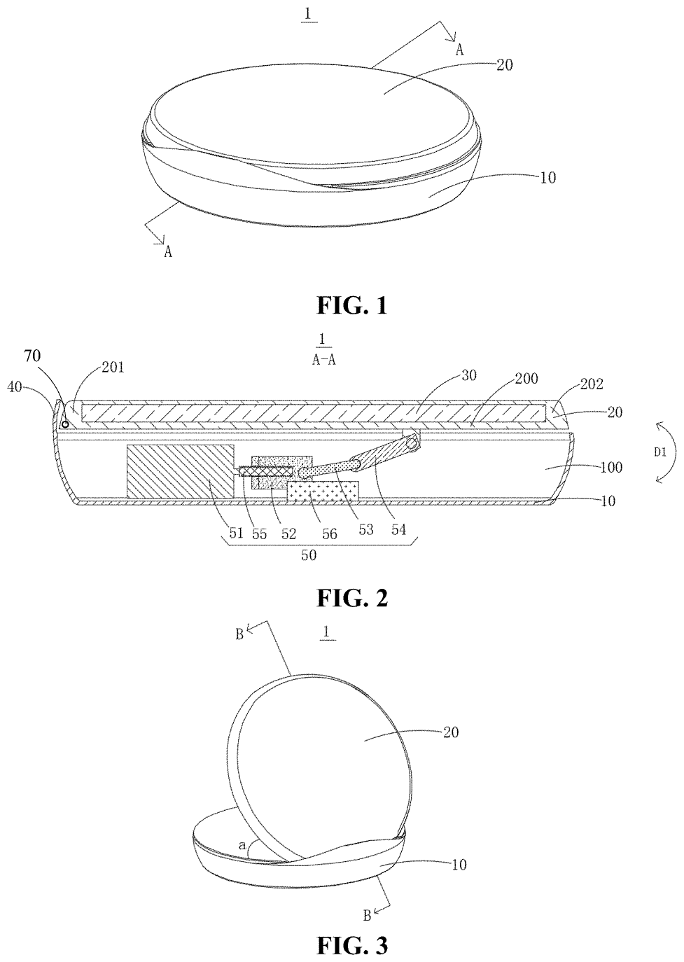

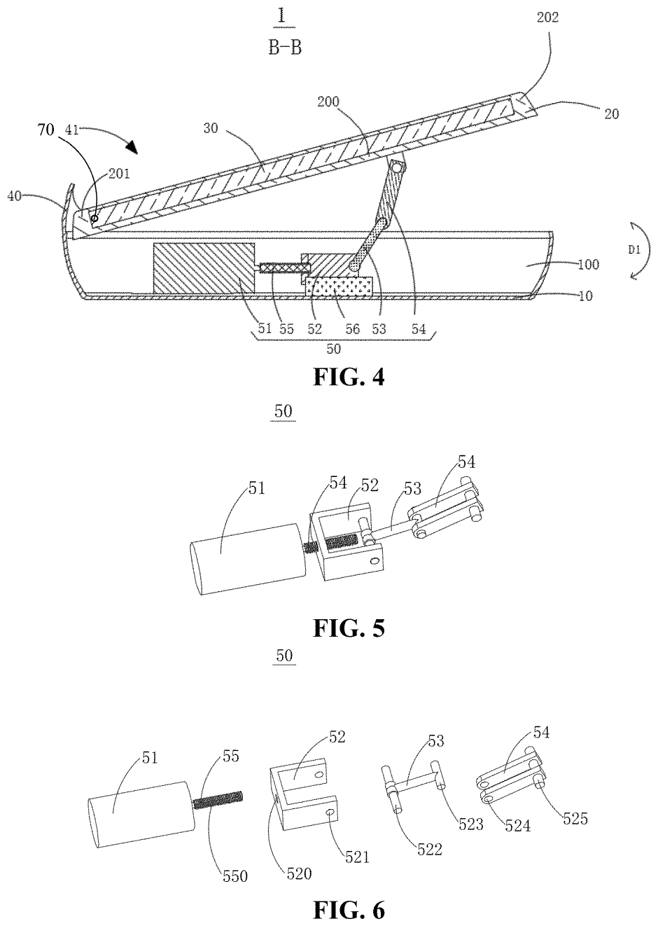

Referring to FIGS. 1-4, FIG. 1 is a schematic perspective structural view of a charging device in a horizontal state in an implementation of the disclosure, FIG. 2 is a schematic cross-sectional view of the charging device in FIG. 1, taken along line A-A, FIG. 3 is a schematic perspective structural view of a charging device in a vertical state in an implementation of the disclosure, and FIG. 4 is a schematic cross-sectional view of the charging device in FIG. 3, taken along line B-B. A charging device 1 is provided in implementations of the disclosure. The charging device 1 has a horizontal state and a vertical state. The charging device 1 may include a first housing 10, a second housing 20, a charging assembly 30, and a motor assembly 50. The first housing 10 defines a first receiving space 100. The second housing 20 is rotatably connected with the first housing 10 and configured to hold an electronic device 2. The charging assembly 30 is received in the second housing 20 and configured to charge the electronic device 2. The motor assembly 50 is received in the first receiving space 100 and configured to drive the second housing 20 to rotate relative to the first housing 10. The second housing 20 has a first end 201 and a second end 202 opposite the first end 201. The second end 202 is farther away from the first housing 10 than the first end 201 when the charging device 1 is in the vertical state. The motor assembly 50 is connected with the second end 202. In the horizontal state, the second housing 20 is parallel to the first housing 10. In the vertical state, the second housing 20 is angled relative to the first housing 10.

The charging device 1 provided in the implementations is mainly configured to charge the electronic device 2. The charging device 1 may be connected with an external power supply, and serve as an intermediate medium to transfer the external electrical energy to charge the electronic device 2. Alternatively, the charging device 1 itself has a battery 5, and the charging device 1 can transfer the electrical energy of its own battery 5 to charge the electronic device 2. In addition, the electronic device 2 may include but is not limited to a mobile terminal such as a mobile phone, a tablet, a laptop, a palmtop, a personal computer (PC), a personal digital assistant (PDA), a portable media player (PMP), a navigation apparatus, a wearable device, a smart bracelet, a pedometer, and a fixed terminal such as a digital television (TV) and a desktop computer. For example, the electronic device 2 is a mobile phone in the disclosure.

The charging device 1 provided in the implementation may include the first housing 10 and the second housing 20. The second housing 20 is configured to hold the electronic device 2. The first housing 10 can be regarded as a lower housing, and the second housing 20 can be regarded as an upper housing. The first housing 10 is rotatably connected with the second housing 20 so that the second housing 20 is rotatable relative to the first housing 10. That is, the first housing 10 remains stationary while the second housing 20 rotates, as illustrated by array D1 in FIG. 2. The electronic device 2 is placed on the second housing 20, and thus when the second housing 20 rotates relative to the first housing 10, the electronic device 2 also rotates together with the second housing 20.

The vertical-horizontal convertible charging device 1 is provided in the implementations, that is, the charging device 1 may have two states: a horizontal state (as illustrated in FIG. 1) and a vertical state (as illustrated in FIG. 3). In the horizontal state, the second housing 20 is parallel to the first housing 10, which can also be understood as that the second housing 20 abuts against a surface of the first housing 10. In the vertical state, the second housing 20 is angled relative to the first housing 10, which can also be understood as that the second housing 20 has rotated relative to the first housing 10, and one end of the second housing 20 has rotated away from the first housing 10, and thus the second housing 20 and the first housing 10 are no longer parallel to each other, and define a certain included angle (illustrated as angle a in FIG. 3). Optionally, in the vertical state, the angle defined between the second housing 20 and the first housing 10 may be greater than 0° and less than 90°, i.e., 0°<a<90°. When the charging device 1 is in the vertical state, the electronic device 2 on the second housing 20 may also rotate together with the second housing 20, “standing” up to meet user's needs for viewing the electronic device 2 at different angles.

The charging device 1 provided in the implementations may also include the charging assembly 30, which is received in a second receiving space 200 of the second housing 20 and is configured to charge the electronic device 2. Optionally, the charging device 1 may transmit electrical energy in a wired manner. Alternatively, the charging device 1 may transmit electrical energy in a wireless manner, e.g., the charging device 1 may be a wireless charging device 1. Therefore, the charging device 1 provided in the disclosure mainly has two functions, i.e., a vertical-horizontal convertible function and a charging function. Optionally, a charging coil 31 is a wireless charging coil 31.

In related technologies, a device with the horizontal-vertical convertible structure is generally switched between horizontal and vertical states manually, without the ability to adjust angles as needed, leading to poor adjustability. Therefore, to solve the above problems, in the implementations, a motor assembly 50 is provided in the first receiving space 100 of the first housing 10, and the motor assembly 50 is connected with the second housing 20. In the implementations, the motor assembly 50 may be controlled to operate to drive the second housing 20 to rotate relative to the first housing 10, thereby achieving an automatic horizontal-vertical convertible function of the charging device 1. By controlling operation of the motor assembly 50, an orientation of the charging device 1 can be adjusted as needed, improving the adjustability of the charging device 1.

In addition, the second housing 20 has a first end 201 and a second end 202 opposite the first end 201. As mentioned above, during switching of the charging device 1 from the horizontal state to the vertical state, the second housing 20 rotates relative to the first housing 10, such that the second end 202 is rotated away from the first housing 10 and the first end 201 is rotated towards the first housing 10 or the inside of the first housing 10. In this way, when the charging device 1 is in the vertical state, the second end 202 is farther away from the first housing 10 than the first end 201. In the implementations, the motor assembly 50 is connected with the second end 202 of the second housing 20. In the implementations, the motor assembly 50 rotates the second housing 20 by pushing the second housing 20 to rotate upwards or outwards, such that the second housing 20 as a whole rotates. In this way, when the electronic device 2 is placed on the charging device 1 in the vertical state, a torque of the motor assembly 50 can be reduced, so that a force exerted on the motor assembly 50 is reduced, and the stability of the charging device 1 is enhanced and the service life of the charging device 1 is prolonged.

Optionally, the charging device 1 may further include a rotating shaft 70, opposite two ends of the rotating shaft 70 are respectively connected with the first housing 10 and the second housing 20, and the second housing 20 is rotatable around the rotating shaft 70. Generally, in order to reduce the overall size of the charging device 1 and increase a rotation angle of the second housing 20, a vertical distance between the rotating shaft 70 and the first end 201 is smaller than a vertical distance between the rotating shaft 70 and the second end 202. In this way, the motor assembly 50 may drive the second housing 20 to rotate with a relatively small driving force, reducing the difficulty of driving the second housing 20 to rotate by the motor assembly 50. The specific structure of the motor assembly 50 will be described in detail below.

Referring to FIG. 2 and FIGS. 4-6 again, FIG. 5 is a schematic perspective structural view of the motor assembly in an implementation of the disclosure, and FIG. 6 is an exploded view of the motor assembly in FIG. 5. In the implementations, the motor assembly 50 may include a motor 51, a slider 52, a first connecting rod 53, and a second connecting rod 54. The motor 51 is connected with the slider 52 and is configured to drive the slider 52 to slide. The first connecting rod 53 has one end rotatably connected with the slider 52 and the other end rotatably connected with one end of the second connecting rod 54. The other end of the second connecting rod 54 is connected with the second housing 20.

In order to achieve that the motor assembly 50 can drive the second housing 20 to rotate, the motor assembly 50 is provided in the implementations. The motor assembly may include the motor 51, the slider 52, the first connecting rod 53, and the second connecting rod 54. The motor 51 is connected with the slider 52 and is configured to drive the slider 52 to slide. During operation of the motor 51, an output shaft of the motor 51 can rotate, thereby driving the slider 52 to slide. In addition, there mainly two manners in which the motor 51 drives the slider 52 to slide. One is that sliding movement of the slider 52 is realized with the aid of a lead screw 55, and the other one is that sliding movement of the slider 52 is realized with the aid of a gear assembly 500. Since one end of the first connecting rod 53 is rotatably connected with the slider 52, when the slider 52 slides, the first connecting rod 53 may not only be driven by the slider 52 to slide together but also rotate around a connection point between the first connecting rod 53 and the slider 52. Since the other end of the first connecting rod 53 is rotatably connected with one end of the second connecting rod 54, when the first connecting rod 53 slides, the second connecting rod 54 may also rotate around a connection point between the second connecting rod 54 and the first connecting rod 53. The other end of the second connecting rod 54 is connected with the second housing 20. Therefore, when the second connecting rod 54 rotates, the second housing 20 may rotate together, thereby achieving rotation of the second housing 20 driven by the motor 51.

Specifically, during a process that the charging device 1 is switched from the horizontal state to the vertical state, i.e., a process that the charging device 1 is switched from a state in FIG. 2 to a state in FIG. 4, the motor 51 starts operation and drives the slider 52 to slide away from the motor 51, the one end of the first connecting rod 53 is also driven by the slider 52 to slide away from the motor 51, and the other end of the first connecting rod 53 rotates counterclockwise around the one end of the first connecting rod 53 towards the second housing 20. The other end of the second connecting rod 54 may also rotate counterclockwise around the one end of the second connecting rod 54. Since the second housing 20 is connected with the other end of the second connecting rod 54, the second housing 20 also rotates counterclockwise under the joint rotation of the first connecting rod 53 and the second connecting rod 54, and then the second housing 20 is rotated and lifted up, and finally reaches the vertical state.

During a process that the charging device 1 is switched from the vertical state to the horizontal state, i.e., a process that the charging device 1 is switched from the state in FIG. 4 to the state in FIG. 2, the motor 51 starts operation and drives the slider 52 to slide towards the motor 51, the one end of the first connecting rod 53 is also driven by the slider 52 to slide towards the motor 51, and the other end of the first connecting rod 53 rotates clockwise around the one end of the first connecting rod 53 close to the first housing 10. The other end of the second connecting rod 54 may also rotate clockwise around the one end of the second connecting rod 54. Since the second housing 20 is connected with the other end of the second connecting rod 54, the second housing 20 also rotates clockwise under the joint rotation of the first connecting rod 53 and the second connecting rod 54, and then the second housing 20 is rotated downward and finally reaches the horizontal state.

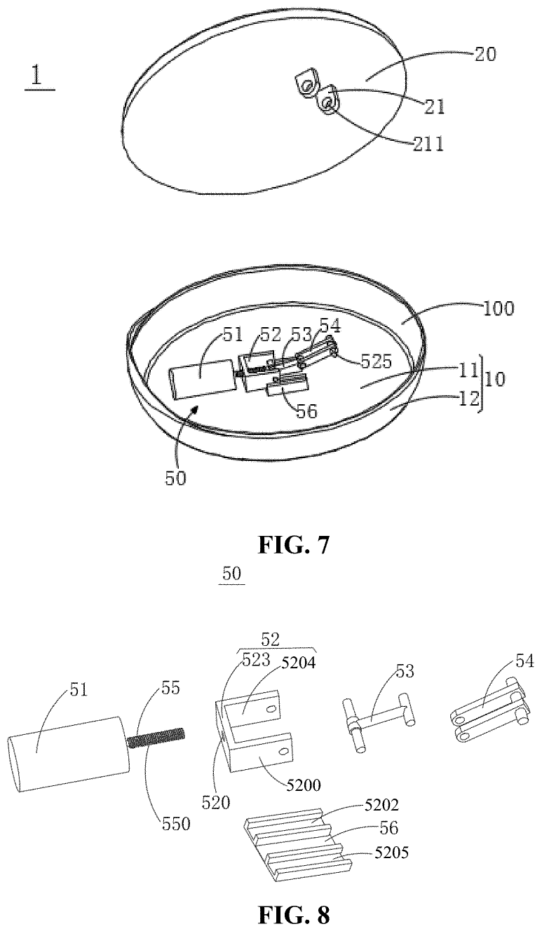

Referring to FIGS. 2, 4, and 7 together, FIG. 7 illustrates an exploded view of the charging device in an implementation of the disclosure. In the implementations, the other end of the second connecting rod 54 is rotatably connected with the second housing 20. The other end of the second connecting rod 54 may also be rotatably connected with the second housing 20, so that the second housing 20 can also rotate around the other end of the second connecting rod 54. For example, during switching of the charging device 1 from the horizontal state to the vertical state, the second housing 20 may also rotate counterclockwise around the other end of the second connecting rod 54, thereby further increasing the rotation angle of the second housing 20. During switching of the charging device 1 from the vertical state to the horizontal state, the second housing 20 may also rotate clockwise around the other end of the second connecting rod 54, thereby reducing a distance between the second connecting rod 54 and the bottom wall 11 of the first housing 10.

Referring to FIG. 6 again, in the implementations, the slider 52 is provided with a first rotating portion 521. The first connecting rod 53 is provided with a second rotating portion 522 at one end of the first connecting rod 53. The first rotating portion 521 cooperates with the second rotating portion 522 to enable the slider 52 to be rotatably connected with one end of the first connecting rod 53.

In the implementations, the first rotating portion 521 may be a rotating groove, a rotating hole, or a rotating block, and the second rotating portion 522 may also be a rotating block, a rotating groove, or a rotating hole. The implementations merely take the first rotating portion 521 as a rotating hole and the second rotating portion 522 as a rotating block for illustration.

Referring to FIG. 6 again, in the implementations, the first connecting rod 53 is provided with a third rotating portion 523 at the other end, and the second connecting rod 54 is provided with a fourth rotating portion 524 at one end. The third rotating portion 523 cooperates with the fourth rotating portion 524 to enable the other end of the first connecting rod 53 to be rotatably connected with one end of the second connecting rod 54.

In the implementations, the third rotating portion 523 may be a rotating groove, a rotating hole, or a rotating block, and the fourth rotating portion 524 may also be a rotating block, a rotating groove, or a rotating hole. The implementations merely take the third rotating portion 523 as a rotating block and the fourth rotating portion 524 as a rotating hole for illustration.

Referring to FIG. 6 and FIG. 7 again, in the implementations, the second connecting rod 54 is provided with a fifth rotating portion 525 at the other end. The second housing 20 is provided with a protruding portion 21 on a side surface of the second housing 20 close to the first housing 10. The protruding portion 21 is provided with a sixth rotating portion 211. The fifth rotating portion 525 cooperates with the sixth rotating portion 211 to enable the other end of the second connecting rod 54 to be rotatably connected with the second housing 20.

In the implementations, the sixth rotating portion 211 may be disposed on the protruding portion 21, and the protruding portion 21 may be connected with the second housing 20, so that the second housing 20 may have a simple structure. Furthermore, in the implementations, the fifth rotating portion 525 may be a rotating groove, a rotating hole, or a rotating block, and the sixth rotating portion 211 may also be a rotating block, a rotating groove, or a rotating hole. The implementations merely take the fifth rotating portion 525 as a rotating block and the sixth rotating portion 211 as a rotating hole for illustration.

Optionally, an axial dimension of the first connecting rod 53 is greater than an axial dimension of the second connecting rod 54. It can also be understood that the first connecting rod 53 is longer than the second connecting rod 54, and thus it is beneficial for that the first connecting rod 53 and the second connecting rod 54 rotate in the same direction, for example, both the first connecting rod 53 and the second connecting rod 54 rotate clockwise or counterclockwise, which causes upward or downward movement of the second housing 20, thereby enhancing a rotation performance of the second housing 20.

Referring to FIGS. 2 and 4-6 again, in the implementations, the motor assembly 50 may further include a lead screw 55. The lead screw 55 has one end rotatably connected with the motor 51, and the slider 52 is sleeved on the lead screw 55. The slider 52 is provided with a first sliding portion 5200. The charging device 1 may further include a second sliding portion 5202 connected with the first housing 10. The first sliding portion 5200 cooperates with the second sliding portion 5202 to enable the slider 52 to slide under rotation of the lead screw 55 driven by the motor 51.

In a first manner provided in the disclosure in which sliding movement is realized with the aid of the lead screw 55, the lead screw 55 is further disposed in the motor assembly 50. The lead screw 55 has one end rotatably connected with the motor 51, and the slider 52 is sleeved on the lead screw 55. The motor 51 in operation may drive the lead screw 55 to rotate together, which in turn drive the slider 52 to slide. In addition, in order to slide rather than rotate the slider 52, in the implementations, the slider 52 is provided with the first sliding portion 5200, and the first sliding portion 5200 cooperates with the second sliding portion 5202 connected with the first housing 10, so that rotation movement of the lead screw 55 can be converted into sliding movement of the slider 52. It can also be understood that the first sliding portion 5200 cooperates with the second sliding portion 5202 to achieve a guiding function, so that a rotation force of the lead screw 55 is converted into a sliding force, thereby driving the slider 52 to slide.

Optionally, the slider 52 may define a threaded hole 520, the lead screw 55 may have threads 550 on a surface of the lead screw 55, and the slider 52 is threadedly connected with the lead screw 55 through the threaded hole 520. In the implementations, the slider 52 is in threaded connection with the lead screw 55 through the threaded hole 520 and the threads 550. Furthermore, the threaded connection between the lead screw 55 and the slider 52 has a certain self-locking property, and thus when the charging device 1 is in the vertical state (that is, when the second housing 20 is rotated to be lifted up), a weight of the second housing 20, a weight of the electronic device 2 placed on the second housing 20, or other external impact forces cannot reverse the motor 51, such that the second housing 20 does not fall down, thereby enhancing the safety of the charging device 1.

In the disclosure, there are two manners in which the first sliding portion 5200 cooperates with the second sliding portion 5202 to slide the slider 52. One is that a sliding block 5204 cooperates with a sliding groove 5205 to guide sliding movement of the slider 52, and the other one is that the guide rod 57 guides sliding movement of the slider 52.

Referring to FIG. 8, which is an exploded view of the motor assembly and a support member in an implementation of the disclosure. In the implementations, the first housing 10 may include a bottom wall 11 and a side wall 12 that is connected with and bent relative to a periphery of the bottom wall 11. The bottom wall 11 and the side wall 12 cooperate to define the first receiving space 100. The charging device 1 may further include a support member 56 connected with the bottom wall 11, and the second sliding portion 5202 is disposed on a side surface of the support member 56 away from the bottom wall 11.

In a first manner provided in the disclosure in which the sliding block 5204 cooperates with the sliding groove 5205 to realize guiding, to realize the above cooperation, in the implementations, the support member 56 is further provided on the bottom wall 11 of the first housing 10, and the second sliding portion 5202 is disposed at the side of the support member 56 away from the bottom wall 11. It can also be understood that the support member 56 is separated from the first housing 10. The second sliding portion 5202 is first disposed on the support member 56, and then the support member 56 is placed on the first housing 10, which can reduce the difficulty of manufacturing the first housing 10.

Referring to FIG. 8 again, in the implementations, the slider 52 may include a connecting portion 523 and sliding blocks 5204 respectively protruding from opposite ends of the connecting portion 523. The connecting portion 523 is sleeved on the lead screw 55. The support member 56 defines a sliding groove 5205 on a side surface of the support member 56 away from the bottom wall 11. The sliding block 5204 cooperates with the sliding grooves 5205 to slide the slider 52.

In addition to the support member 56, the slider 52 may further include the connecting portion 523 and the sliding blocks 5204 respectively protruding from opposite ends of the connecting portion 523. In the implementations, the sliding block 5204 may be divided into two parts, where the connecting portion 523 is sleeved on the lead screw 55 and the sliding blocks 5204 serve as the first sliding portion 5200. The support member 56 defines the sliding groove 5205 at the side of the support member 56 away from the bottom wall 11, and the sliding groove 5205 serves as the second sliding portion 5202. In the implementations, the sliding blocks 5204 cooperate with the sliding groove 5205, so that rotation movement of the slider 52 can be converted into sliding movement, and the sliding blocks 5204 can slide in the sliding groove 5205 in a directed manner.

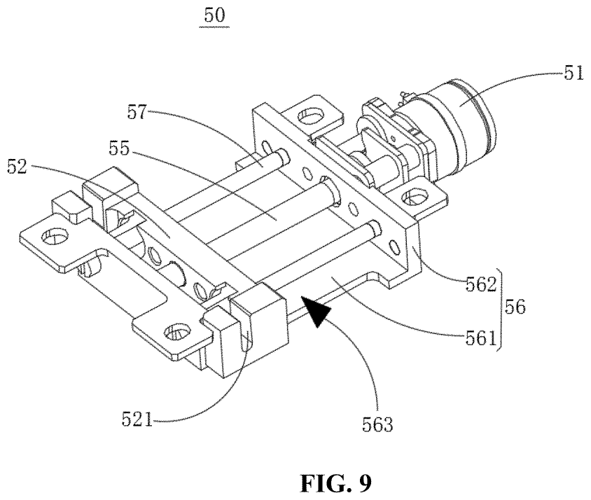

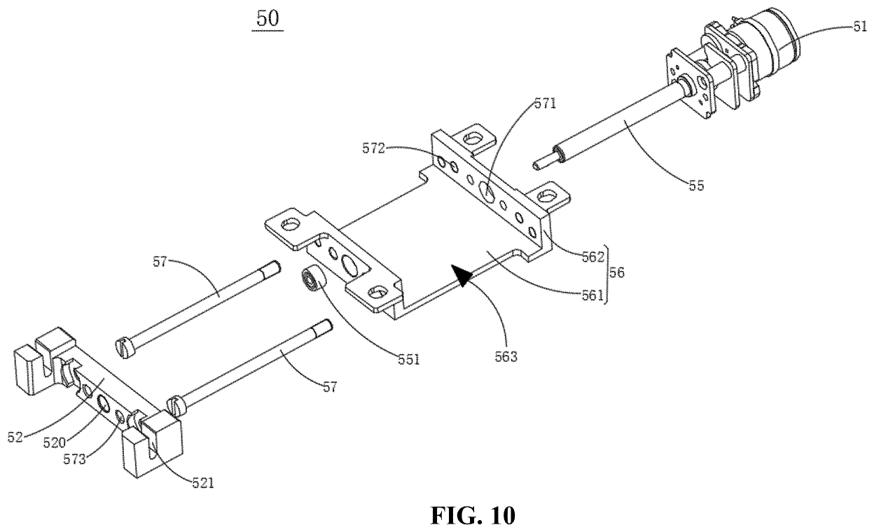

Referring to FIG. 9 and FIG. 10, FIG. 9 is a schematic partial structural view of a motor assembly in another implementation of the disclosure, and FIG. 10 is an exploded view of the motor assembly in FIG. 9. In the implementations, the motor assembly 50 may further include the support member 56 and the guide rod 57. The support member 56 may include a bottom plate 561 and side plates 562 that are respectively connected with and bent relative to opposite ends of the bottom plate 561. The bottom plate 561 and the side plates 562 cooperate to define a sliding space 563. The slider 52 is received in the sliding space 563. The side plate 562 defines a first through hole 571. The lead screw 55 extends through the first through hole 571 and the slider 52. The side plate 562 defines a second through hole 572. The slider 52 defines a third through hole 573. The guide rod 57 is connected with the side plates 562 and extends through the second through hole 572 and the third through hole 573. The slider 52 is slidable on the guide rod 57 through the third through hole 573.

In a second manner provided in the disclosure in which the sliding movement is realized with the aid of the guiding of the guide rod 57, the support member 56 and the guide rod 57 may be further provided. In the implementations, the support member 56 may include the bottom plate 561 and the side plates 562. The bottom plate 561 and the side plates 562 may cooperate to define the sliding space 563, so that the slider 52 can slide in the sliding space 563. Additionally, the side plate 562 defines the first through hole 571. The lead screw 55 extends through the first through hole 571 and the threaded hole 520 of the slider 52, so that the lead screw 55 is mounted at the side plate 562. The side plate 562 also defines the second through hole 572. The slider 52 defines the third through hole 573. The guide rod 57 extends through the second through hole 572 and the third through hole 573 and is connected with the side plate 562. In this way, rotation movement of the slider 52 can be converted into sliding movement with the aid of the guiding of the guide rod 57, and thus the slider 52 slides in an axial direction of the lead screw 55.

Optionally, the guide rod 57 can be implemented as one or more guide rods 57. The implementations take two guide rods 57 for illustration.

Optionally, the motor 51 may be fixedly connected with the support member 56 via screws, and the guide rod 57 may be fixedly connected with the threaded hole at one end of the support member 56 via the threads at one end of the guide rod 57. Optionally, a bearing 551 may also be provided in the first through hole 571, and the bearing 551 is sleeved on one end of the lead screw 55. The bearing 551 may cooperate with the lead screw 55 and the support member 56 to improve rotation performance of the lead screw 55.

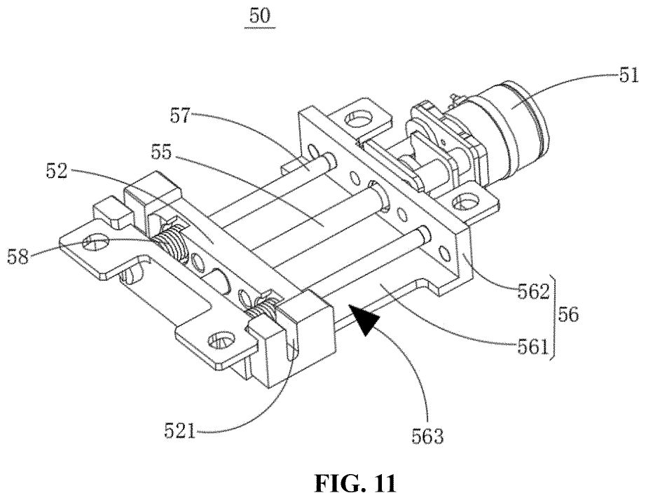

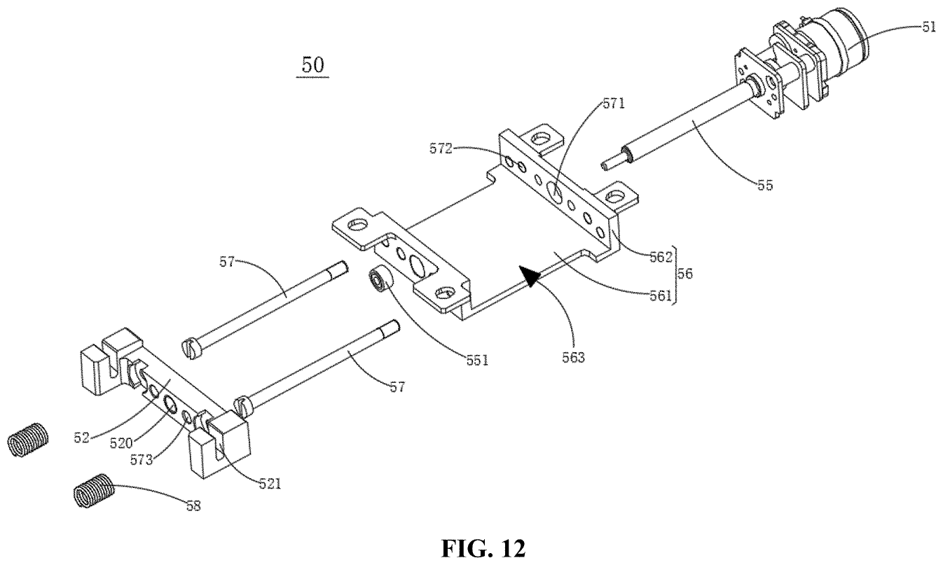

Referring to FIG. 11 and FIG. 12, FIG. 11 is a schematic partial structural view of a motor assembly in yet another implementation of the disclosure, and FIG. 12 is an exploded view of the motor assembly in FIG. 11. In the implementations, the motor assembly 50 may further include an elastic member 58 received in the sliding space 563 and sleeved on the guide rod 57. The elastic member 58 is disposed between the side plate 562 and the slider 52. The elastic member 58 abuts against the side plate 562 and the slider 52 and is in a compressed state when the charging device 1 is in the horizontal state.

In the implementations, the elastic member 58 may also be further provided in the motor assembly 50, and the elastic member 58 is sleeved on the guide rod 57 and disposed between the side plate 562 and the slider 52. When the charging device 1 is in the horizontal state (i.e., when the motor 51 of the charging device 1 is not in operation or has stopped), the elastic member 58 abuts against the side plate 562 and the slider 52, and thus is in a compressed state. Thus, when the charging device 1 starts to operate, the elastic member 58 may provide the slider 52 with an elastic restoring force in a direction towards the motor 51, so that the slider 52 can slide towards the motor 51 more easily. As such, the second housing 20 can be lifted up more easily at an initial stage, and thus the rotation performance of the second housing 20 is further enhanced. Optionally, the elastic member 58 may include but is not limited to a spring.

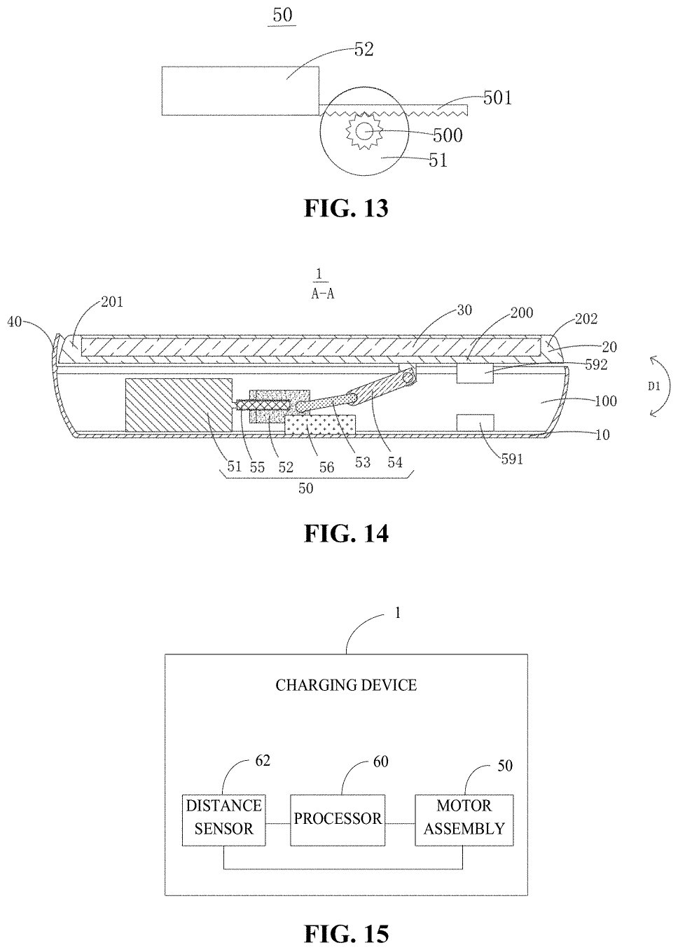

Referring to FIG. 13, FIG. 13 is a schematic structural view of a motor assembly in yet another implementation of the disclosure. In the implementations, the motor assembly 50 may further include the gear assembly 500 and a rack 501. The gear assembly 500 has one end rotatably connected with the motor 51 and the other end meshed with the rack 501. The rack 501 is connected with the slider 52. The motor 51 is configured to drive the gear assembly 500 to rotate, the rack 501 is configured to move with rotation of the gear assembly 500, and the slider 52 is configured to slide with movement of the rack 501.

The above describes the first manner provided in the disclosure in which the sliding movement is realized with the aid of the lead screw 55. In the implementations, another manner in which the sliding movement is realized with the aid of the gear assembly 500 is provided in the disclosure. The gear assembly 500 and the rack 501 are further provided, one end of the gear assembly 500 is connected with the motor 51, and the other end of the gear assembly 500 is meshed with the rack 501, and the rack 501 is connected with the slider 52. In this way, the gear assembly 500 is meshed with the rack 501, and thus when the motor 51 drives the gear assembly 500 to rotate, rotation of the gear assembly 500 can be converted into movement of the rack 501. The movement of the rack 501 drives the slider 52 to slide. In the implementations, the gear assembly 500 and the rack 501 cooperate to convert rotation movement into sliding movement, so that driving components have simple structure. Additionally, a speed of the slider 52 may be adjusted by adjusting the number (quantity) and size of the teeth in the gear assembly 500. Optionally, the gear assembly 500 may include gears rotatably connected with each other.

Referring to FIG. 4 again, in the implementations, the first housing 10 may include a bottom wall 11 and a side wall 12 that is connected with and bent relative to a periphery of the bottom wall 11. A holder 40 is disposed on a side surface of at least part of the side wall 12 away from the bottom wall 11. The at least part of the side wall 12 is close to the first end 201. The holder 40 and a side surface of the second housing 20 away from the bottom wall 11 cooperate to define a positioning recess 41 when the charging device 1 is in the vertical state, where the positioning recess 41 is configured to position the electronic device 2.

During switching of the charging device 1 from the horizontal state to the vertical state, that is, during rotation of the second housing 20 relative to the first housing 10, the electronic device 2 placed on the second housing 20 may also rotate, resulting in that the electronic device 2 may slide downwards due to its own gravity. Optionally, the holder 40 is further provided on the first housing 10. When the electronic device 2 is in the vertical state, the holder 40 and the side surface of the second housing 20 away from the first housing 10 cooperate to define the positioning recess 41. The holder 40 may be configured to support one end of the electronic device 2 to prevent the electronic device 2 from sliding down.

Optionally, the holder 40 and the first housing 10 may be integrally formed. However, in order to distinguish their structures better, the holder 40 and the first housing 10 are divided into two parts.

Optionally, referring to FIG. 2 again, when the charging device 1 is in the horizontal state, a side surface of the holder 40 away from the first housing 10 is flush with a side surface of the second housing 20 away from the first housing 10. Therefore, the holder 40 does not exceed the second housing 20 when the charging device 1 is in the horizontal state, which improves a flatness of the charging device 1 and makes it more convenient to place the electronic device 2 on the charging device 1 as needed.

Referring to FIG. 14, FIG. 14 is a schematic cross-sectional view of the charging device in FIG. 1 in another implementation of the disclosure, taken along line A-A. In the implementations, the charging device 1 may further include a first magnetic member 591 connected with the first housing 10 and a second magnetic member 592 connected with the second housing 20. The first magnetic member 591 cooperates with the second magnetic member 592 to generate repulsion force when the charging device 1 is switched to the vertical state from the horizontal state.

In the implementations, the first magnetic member 591 and the second magnetic member 592 may be further provided in the charging device 1. Both the first magnetic member 591 and the second magnetic member 592 may have magnetic properties. Optionally, the first magnetic member 591 and the second magnetic member 592 may include but are not limited to permanent magnets or electromagnets. The first magnetic member 591 is connected with the first housing 10, and the second magnetic member 592 is connected with the second housing 20. During switching of the charging device 1 from the horizontal state to the vertical state, the first magnetic member 591 and the second magnetic member 592 cooperate to generate a repulsion force, thereby further reducing the difficulty of lifting up the second housing 20 and enhancing the rotation performance of the second housing 20. Additionally, in structure, the above can also be understood as that the first magnetic member 591 has a first electrode and a second electrode opposite the first electrode, and the second magnetic member 592 also has a first electrode and a second electrode opposite the first electrode. When the charging device 1 is in the horizontal state, the first electrode of the first magnetic member 591 faces the first electrode of the second magnetic member 592, thereby reducing the difficulty of rotating and lifting up the second housing 20 due to that like poles repel each other. Optionally, the first electrode may be a north pole and the second electrode may be a south pole. Alternatively, the first electrode may be a south pole and the second electrode may be a north pole.

In addition, in the disclosure, the charging device may further include a processor 60 received in the first receiving space 100. The processor 60 is electrically connected with the motor assembly 50, configured to send a first control signal to the motor assembly 50 to start the motor assembly 50, and further configured to send a second control signal to the motor assembly 50 to stop the motor assembly 50. The processor 60 may send different control signals to control specific operations of the motor assembly 50. The following will describe specifically several implementations in which operation of the motor assembly 50 is controlled through cooperation between the processor 60 and other electronic structural members.

Referring to FIG. 15, FIG. 15 is a schematic structural view of an electronic structure of a charging device in an implementation of the disclosure. In the implementations, the charging device 1 may further include a distance sensor 62 received in the first receiving space 100. The distance sensor 62 is electrically connected with the processor 60 and connected with the motor assembly 50. The processor 60 is configured to send the first control signal to the motor assembly 50 to start the motor assembly 50. During operation of the motor assembly 50, the distance sensor 62 is configured to send a distance signal to the processor 60, and the processor 60 is further configured to obtain the rotation angle of the second housing 20 according to the distance signal. The processor 60 is further configured to determine whether the rotation angle of the second housing 20 is greater than or equal to a preset angle, and further configured to send the second control signal to the motor assembly 50 to stop the motor assembly 50 in response to the rotation angle of the second housing 20 being greater than or equal to the preset angle.

In addition to the above-mentioned mechanical structural members of the charging device 1, in the implementations, the charging device 1 may further include structural members with electronic control functions such as the processor 60 and the distance sensor 62. The distance sensor 62 is received in the first receiving space 100, connected with the motor assembly 50, and electrically connected with the processor 60. The processor 60 is configured to send the first control signal to the motor assembly 50 to start the motor assembly 50. During operation of the motor assembly 50, the distance sensor 62 is configured to detect a displacement distance (i.e. a distance that the slider 52 slides) of at least part of the motor assembly 50 to obtain a distance signal, then the distance sensor 62 sends the distance signal to the processor 60, and the processor 60 can obtain the rotation angle of the second housing 20 relative to the first housing 10 according to the distance signal.

In addition, the processor 60 can also determine a relationship between the rotation angle of the second housing 20 and the preset angle. The preset angle may be pre-stored in the charging device 1 or obtained by the charging device 1 from the outside in real time, for example, the preset angle may be input to the charging device 1 by a user. The preset angle may be understood as a maximum rotation angle of the second housing 20 allowed by the charging device 1 or a rotation angle of the second housing 20 desired by the user.

When the rotation angle of the second housing 20 is greater than or equal to the preset angle, it indicates that the second housing 20 has rotated by an angle set by the user and no further rotation is desired. Therefore, the processor 60 is further configured to send the second control signal to the motor assembly 50 to stop the motor assembly 50, thereby stopping rotation of the second housing 20 and allowing the charging device 1 to reach the vertical state desired by the user.

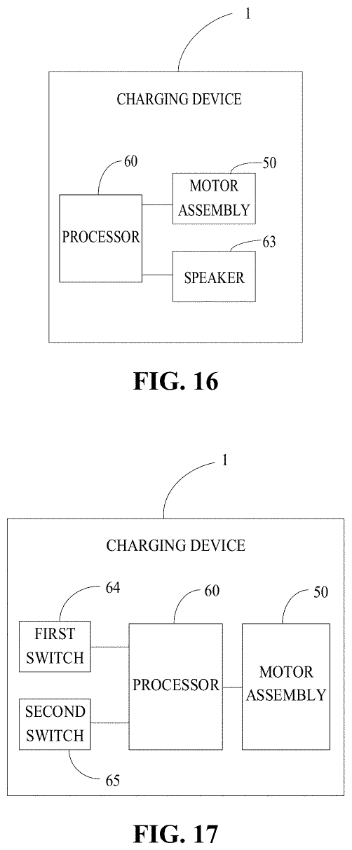

Referring to FIG. 16, FIG. 16 is a schematic structural view of an electronic structure of the charging device in another implementation of the disclosure. In the implementations, the charging device 1 may further include a speaker 63 received in the first receiving space 100 and electrically connected with the processor 60. The processor 60 is further configured to send an audio signal to the speaker 63 to make the speaker 63 sound when the processor 60 sends the first control signal to the motor assembly 50. The processor 60 is further configured to stop sending the audio signal to the speaker 63 when the processor 60 sends the second control signal to the motor assembly 50.

In the implementations, the speaker 63 is provided in the first receiving space 100 and is electrically connected with the processor 60. When the processor 60 sends the first control signal to the motor assembly 50, the motor assembly 50 starts operation, and at this point, the processor 60 can send the audio signal to the speaker 63 to make the speaker 63 sound. The motor assembly 50 may produce slight noise during operation. Sound of the speaker 63 can be used to make the noise be not heard, which improves user experience in combination with movement of the charging device 1. In addition, when the processor 60 sends the second control signal to the motor assembly 50 to stop the motor assembly 50, the motor assembly 50 does not sound, and at this point, the processor 60 can stop sending the audio signal to the speaker 63 to make the speaker 63 not sound. Moreover, a time point at which the charging device 1 starts operation and a time point at which the charging device 1 stops operation can also be known by a user according to a time point at which the speaker 63 sounds. Optionally, the first housing 10 defines multiple speaker holes to facilitate transmission of the sound emitted by the speaker 63 to the outside of the charging device 1.

Referring to FIG. 17, FIG. 17 is a schematic structural view of an electronic structure of the charging device in yet another implementation of the disclosure. In the implementations, the charging device 1 may further include a first switch 64 and a second switch 65 received in the first receiving space 100, and both the first switch 64 and the second switch 65 are electrically connected with the processor 60.

The first switch 64 is configured to send a vertical signal to the processor 60 in response to pressing of the first switch 64, and the processor 60 is further configured to send the first control signal to the motor assembly 50 according to the vertical signal, the motor assembly 50 is configured to drive the second housing 20 to rotate in a first direction. The second switch 65 is configured to send a horizontal signal to the processor 60 in response to pressing of the second switch 65, and the processor 60 is further configured to send a third control signal to the motor assembly 50 according to the horizontal signal, the motor assembly 50 is configured to drive the second housing 20 to rotate in a second direction, where the first direction is opposite to the second direction.

In the implementations, the first switch 64 and the second switch 65 are provided in the first receiving space 100, connected with the first housing 10, and are electrically connected with the processor 60. The first switch 64 and the second switch 65 are structural members that are configured to control a time when the charging device 1 starts operation. Both the first switch 64 and the second switch 65 can be pressed. The first switch 64 can send the vertical signal to the processor 60 in response to pressing of the first switch 64, and the processor 60 can send the first control signal to the motor assembly 50 according to the vertical signal, thereby starting the motor assembly 50, the motor assembly 50 is configured to drive the second housing 20 to rotate in the first direction. It can also be understood as that when the first switch 64 is pressed, the motor assembly 50 starts operation to switch the charging device 1 from the horizontal state to the vertical state. The second switch 65 can send the horizontal signal to the processor 60 in response to pressing of the second switch 65, and the processor 60 is further configured to send the third control signal to the motor assembly 50 according to the horizontal signal, thereby restarting the motor assembly 50, so that the motor assembly 50 drives the second housing 20 to rotate in the second direction. It can also be understood as that when the second switch 65 is pressed, the motor assembly 50 starts operation to switch the charging device 1 from the vertical state to the horizontal state.

To sum up, the first switch 64 is configured to control the charging device 1 to switch from the horizontal state to the vertical state. The second switch 65 is configured to control the charging device 1 to switch from the vertical state to the horizontal state. The user can control the state of the charging device 1 by pressing of the two switches, which improves convenience of operation.

Referring to FIG. 17 again, in the implementations, the processor 60 is further configured to obtain a pressing duration of the first switch 64 according to the vertical signal and determine whether the pressing duration is less than a preset duration. The processor 60 is configured to send the second control signal to the motor assembly 50 in response to the pressing duration being less than the preset duration and the rotation angle of the second housing 20 being equal to the preset angle, or the processor 60 is configured to send the second control signal to the motor assembly 50 in response to the pressing duration being greater than or equal to the preset duration and removal of a touch force on the first switch 64.

To prevent continuous rotation of the second housing 20 relative to the first housing 10, when the first switch 64 is pressed and the charging device 1 is switched from the horizontal state to the vertical state, operation of the motor assembly 50 needs to be stopped after the second housing 20 have rotated by a certain angle, thereby stopping rotation of the second housing 20. In the implementations, the processor 60 further can obtain the pressing duration of the first switch 64 according to the vertical signal, and determine a relationship between the pressing duration and the preset duration. The preset duration may be pre-stored in the charging device 1 or obtained by the charging device 1 from the outside in real time.

In the implementations, two control manners are provided according to the relationship between the pressing duration and the preset duration. In one control manner, the processor 60 sends the second control signal to the motor assembly 50 to stop the motor assembly 50 in response to the pressing duration being less than the preset duration and the rotation angle of the second housing 20 being equal to the preset angle. It can also be understood as that when the second housing 20 rotates to the maximum angle, the processor 60 can control the motor assembly 50 to stop operation. In the other control manner, the processor 60 can send the second control signal to the motor assembly 50 to stop the motor assembly 50 in response to the pressing duration being greater than or equal to the preset duration and removal of the touch force on the first switch 64. It can also be understood as that when the pressing duration of the first switch 64 is greater than the preset duration, the user needs to remove a pressing force exerted on the first switch 64, so that the motor assembly 50 can be stopped and the second housing 20 can stop rotation at any position.

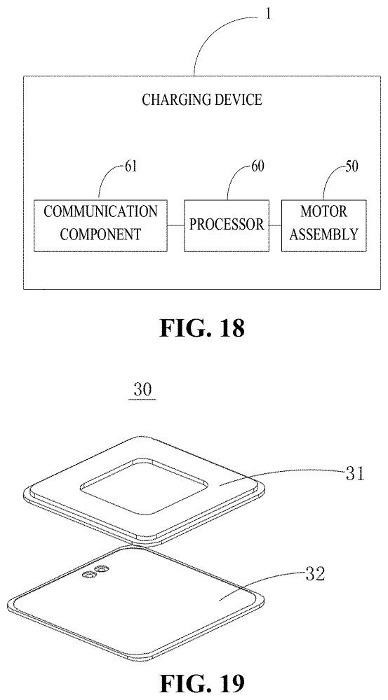

Referring to FIG. 18, FIG. 18 is a schematic structural view of an electronic structure of a charging device in yet another implementation of the disclosure. In the implementations, the charging device 1 may further include a communication component 61 received in the first receiving space 100. The communication component 61 is electrically connected with the processor 60 and configured to receive a fourth control signal from a terminal device. The communication component 61 is further configured to send the fourth control signal to the processor 60, and the processor 60 is further configured to start or stop the motor assembly 50 according to the fourth control signal.

In the implementations, the communication component 61 is provided in the first receiving space 100 and is electrically connected with the processor 60. The communication component 61 is configured to receive the fourth control signal from the terminal device. The terminal device may be an external device such as a mobile phone, a computer, a server, etc. These devices may send the fourth control signal, and the communication component 61 may receive the fourth control signal. The communication component 61 then sends the fourth control signal to the processor 60, and the processor 60 can control operation of the motor assembly 50 according to the fourth control signal, such that the second housing 20 can rotate relative to the first housing 10, and thus realizing switching of the charging device 1 between the horizontal state and the vertical state. Optionally, the communication component 61 may include, but is not limited to, wireless fidelity (Wi-Fi), a Bluetooth, near field communication (NFC), or the like.

Referring to FIG. 2 and FIG. 19 together, FIG. 19 is an exploded view of the charging assembly in an implementation of the disclosure. In the implementations, the second housing 20 defines the second receiving space 200. The charging device 1 may further include the charging assembly 30 received in the second receiving space 200. The charging assembly 30 may include the charging coil 31 and a heat dissipation support 32. The charging coil 31 is disposed on the heat dissipation support 32 and electrically connected with the processor 60. The processor 60 is further configured to send a charging signal to the charging coil 31 to enable the charging coil 31 to charge the electronic device 2.

In the implementations, the second receiving space 200 is defined in the second housing 20, and the charging assembly 30 is received in the second receiving space 200. The charging assembly 30 may include the charging coil 31 and the heat dissipation support 32. The charging coil 31 is a structural member mainly configured to charge the electronic device 2. The heat dissipation support 32 is configured to hold the charging coil 31 and dissipates heat from the charging coil 31, so as to discharge in time the heat generated by operation of the charging coil 31 and improve a heat dissipation performance of the charging coil 31. In addition, the charging coil 31 is electrically connected with the processor 60, and the processor 60 is further configured to send the charging signal to the charging coil 31 to enable the charging coil 31 to charge the electronic device 2. Optionally, the charging coil 31 may be the wired charging coil 31 or the wireless charging coil 31. For example, in the implementations, the charging coil 31 is the wireless charging coil 31, and in this case, the charging device 1 is the wireless charging device 1, which can further improve convenience of usage of the charging device 1.

In addition, the charging assembly 30 may further include a refrigeration member. The refrigeration member is disposed on the heat dissipation support 32 and configured to cool the charging coil 31. Specifically, the refrigeration member is electrically connected with the processor 60, and the processor 60 is further configured to send a cooling signal to the refrigeration member so that the refrigeration member cools the charging coil 31, thereby further discharging in time the heat generated by the charging coil 31 during operation and further improving the heat dissipation performance of the charging coil 31. Optionally, the refrigeration member may include, but is not limited to, a thermo-electronic chip (TEC).

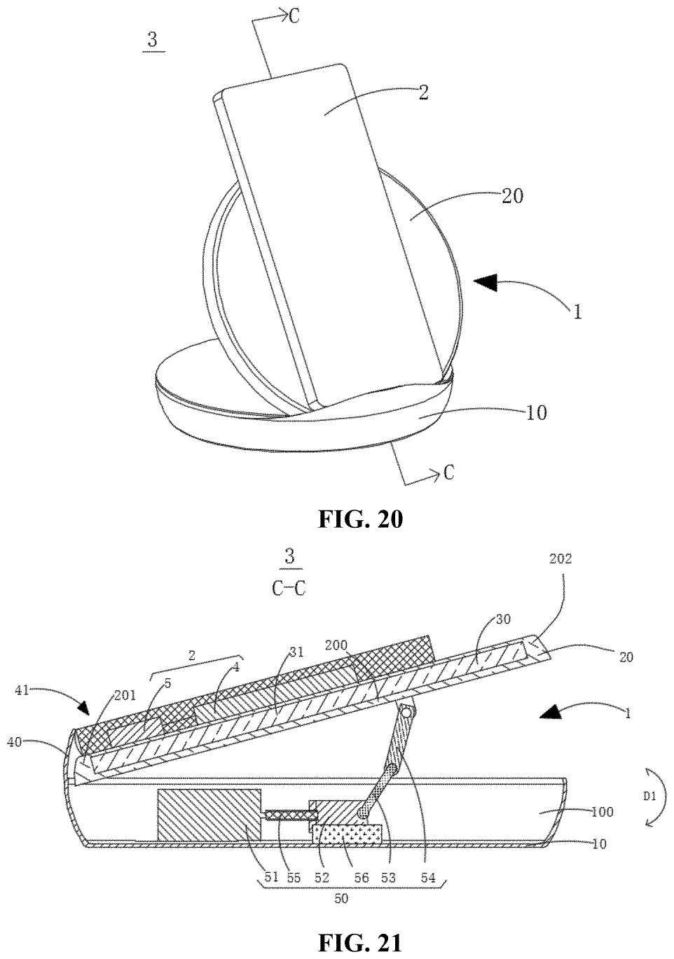

Referring to FIG. 20 and FIG. 21, FIG. 20 is a schematic structural view of an electronic device assembly in an implementation of the disclosure, and FIG. 21 is a schematic cross-sectional view of the electronic device assembly in FIG. 20, taken along line C-C. An electronic device assembly 3 is provided in an implementation. The electronic device assembly 3 may include the electronic device 2 and the charging device 1 provided in the above implementations of the disclosure. The electronic device 2 may include an induction coil 4 and a battery 5, and the charging coil 31 and the induction coil 4 cooperate to charge the battery 5.

Specific structures of the charging device 1 are described above in the disclosure, the electronic device assembly 3 with the charging device 1 is further provided in the disclosure. In the implementations, the electronic device assembly 3 may include the electronic device 2 and the charging device 1 provided in the above implementations of the disclosure. The electronic device 2 may include, but is not limited to, a mobile terminal device such as a mobile phone, a tablet computer, a notebook computer, a palmtop computer, a PC, a PDA, a PMP, a navigation apparatus, a wearable device, a smart bracelet, or a pedometer, or a fixed terminal device such as a digital TV, a desktop computer, etc. The electronic device 2 may include the induction coil 4 and the battery 5. When the charging device 1 starts charging, the charging coil 31 and the induction coil 4 cooperate to charge the battery 5. The electronic device assembly provided in the implementation can be automatically switched between the vertical state and the horizontal state, by adopting the charging device provided in the above-mentioned implementation disclosure, to charge the electronic device, thereby improving the adjustability of the charging device. In addition, connecting the motor assembly to the second end can also improve the stability and service life of the electronic device assembly.

The implementations of the disclosure are described in detail above. Principles and implementation manners of the disclosure are elaborated and explained herein. The above illustrations are merely used to help understanding of methods and core ideas of the disclosure. Moreover, those skilled in the art may make modifications to the specific implementation manners and application scopes according to the ideas of the disclosure. In summary, contents of this specification should not be construed as limiting the disclosure.

1. A charging device, wherein the charging device has a horizontal state and a vertical state and comprises:
a first housing defining a first receiving space;
a second housing rotatably connected with the first housing and configured to hold an electronic device;
a charging assembly received in the second housing and configured to charge the electronic device; and
a motor assembly received in the first receiving space and configured to drive the second housing to rotate relative to the first housing, wherein the second housing has a first end and a second end opposite the first end, the second end is farther away from the first housing than the first end when the charging device is in the vertical state, and wherein the motor assembly is connected with the second end;
wherein in the horizontal state, the second housing is parallel to the first housing, and in the vertical state, the second housing is angled relative to the first housing.

2. The charging device of claim 1, wherein the motor assembly comprises a motor, a slider, a first connecting rod, and a second connecting rod, wherein the motor is connected with the slider and configured to drive the slider to slide, the first connecting rod has one end rotatably connected with the slider and another end rotatably connected with one end of the second connecting rod, and another end of the second connecting rod is connected with the second housing.

3. The charging device of claim 2, wherein the motor assembly further comprises a lead screw, wherein the lead screw has one end rotatably connected with the motor, and the slider is sleeved on the lead screw; the slider is provided with a first sliding portion; and the charging device further comprises a second sliding portion connected with the first housing, wherein the first sliding portion cooperates with the second sliding portion to enable the slider to slide under rotation of the lead screw driven by the motor.

4. The charging device of claim 3, wherein the first housing comprises a bottom wall and a side wall that is connected with and bent relative to a periphery of the bottom wall, wherein the bottom wall and the side wall cooperate to define the first receiving space; the charging device further comprises a support member connected with the bottom wall, and the second sliding portion is disposed on a side surface of the support member away from the bottom wall.

5. The charging device of claim 4, wherein the slider comprises a connecting portion and sliding blocks respectively protruding from opposite ends of the connecting portion, wherein the connecting portion is sleeved on the lead screw, the support member defines sliding grooves on the side surface of the support member away from the bottom wall, and the sliding blocks cooperate with the sliding grooves to slide the slider.

6. The charging device of claim 3, wherein the motor assembly further comprises a support member and a guide rod, wherein the support member comprises a bottom plate and side plates that are respectively connected with and bent relative to opposite ends of the bottom plate, the bottom plate and the side plates cooperate to define a sliding space, and the slider is received in the sliding space, wherein the side plate defines a first through hole, and the lead screw extends through the first through hole and the slider, and wherein the side plate defines a second through hole, the slider defines a third through hole, the guide rod is connected with the side plate and extends through the second through hole and the third through hole, and the slider is slidable on the guide rod through the third through hole.

7. The charging device of claim 6, wherein the motor assembly further comprises an elastic member received in the sliding space and sleeved on the guide rod, wherein the elastic member is disposed between the side plate and the slider, and the elastic member abuts against the side plate and the slider and is in a compressed state when the charging device is in the horizontal state.

8. The charging device of claim 2, wherein the motor assembly further comprises a gear assembly and a rack, wherein the gear assembly has one end rotatably connected with the motor and the other end meshed with the rack, the rack is connected with the slider, and the motor is configured to drive the gear assembly to rotate, the rack is configured to move with rotation of the gear assembly, and the slider is configured to slide with movement of the rack.

9. The charging device of claim 2, wherein the slider is provided with a first rotating portion, the first connecting rod is provided with a second rotating portion at one end of the first connecting rod, and the first rotating portion cooperates with the second rotating portion to enable the slider to be rotatably connected with the one end of the first connecting rod.

10. The charging device of claim 2, wherein the first connecting rod is provided with a third rotating portion at the other end, the second connecting rod is provided with a fourth rotating portion at one end, and the third rotating portion cooperates with the fourth rotating portion to enable the other end of the first connecting rod to be rotatably connected with the one end of the second connecting rod.

11. The charging device of claim 2, wherein the another end of the second connecting rod is rotatably connected with the second housing, the second connecting rod is provided with a fifth rotating portion at the other end, the second housing is provided with a protruding portion on a side surface of the second housing close to the first housing, the protruding portion is provided with a sixth rotating portion, wherein the fifth rotating portion cooperates with the sixth rotating portion to enable the other end of the second connecting rod to be rotatably connected with the second housing.

12. The charging device of claim 1, wherein the first housing comprises a bottom wall and a side wall that is connected with and bent relative to a periphery of the bottom wall, wherein a holder is disposed on a side surface of at least part of the side wall away from the bottom wall, wherein the at least part of the side wall is close to the first end; and wherein the holder and a side surface of the second housing away from the bottom wall cooperate to define a positioning recess when the charging device is in the vertical state, wherein the positioning recess is configured to position the electronic device.

13. The charging device of claim 1, further comprising a first magnetic member connected with the first housing and a second magnetic member connected with the second housing, wherein the first magnetic member cooperates with the second magnetic member to generate repulsive force when the charging device is switched to the vertical state from the horizontal state.

14. The charging device of claim 1, further comprising a processor received in the first receiving space and electrically connected with the motor assembly, wherein the processor is configured to send a first control signal to the motor assembly to start the motor assembly, and configured to send a second control signal to the motor assembly to stop the motor assembly.

15. The charging device of claim 14, further comprising a distance sensor received in the first receiving space, wherein the distance sensor is electrically connected with the processor and connected with the motor assembly; and
wherein during operation of the motor assembly, the distance sensor is configured to send a distance signal to the processor, and the processor is further configured to obtain a rotation angle of the second housing according to the distance signal, and wherein the processor is further configured to determine whether the rotation angle of the second housing is greater than or equal to a preset angle, and the processor is further configured to send the second control signal to the motor assembly to stop the motor assembly in response to the rotation angle of the second housing being greater than or equal to the preset angle.

16. The charging device of claim 14, wherein the charging device further comprises a speaker received in the first receiving space and electrically connected with the processor, wherein the processor is further configured to send an audio signal to the speaker to make the speaker sound when the processor sends the first control signal to the motor assembly, and wherein the processor is further configured to stop sending the audio signal to the speaker when the processor sends the second control signal to the motor assembly.

17. The charging device of claim 14, further comprising a first switch and a second switch received in the first receiving space, wherein both the first switch and the second switch are electrically connected with the processor; and
wherein the first switch is configured to send a vertical signal to the processor in response to pressing of the first switch, and the processor is further configured to send the first control signal to the motor assembly according to the vertical signal, the motor assembly is configured to drive the second housing to rotate in a first direction; and the second switch is configured to send a horizontal signal to the processor in response to pressing of the second switch, and the processor is further configured to send a third control signal to the motor assembly according to the horizontal signal, the motor assembly is configured to drive the second housing to rotate in a second direction, wherein the first direction is opposite to the second direction.

18. The charging device of claim 17, wherein the processor is further configured to obtain a pressing duration of the first switch according to the vertical signal and determine whether the pressing duration is less than a preset duration, and the processor is configured to send the second control signal to the motor assembly in response to the pressing duration being less than the preset duration and the rotation angle of the second housing being equal to the preset angle, or the processor is configured to send the second control signal to the motor assembly in response to the pressing duration being greater than or equal to the preset duration and removal of a touch force on the first switch.

19. The charging device of claim 14, wherein the second housing defines a second receiving space, and the charging device further comprises the charging assembly received in the second receiving space, wherein the charging assembly comprises a charging coil and a heat dissipation support, the charging coil is disposed on the heat dissipation support and electrically connected with the processor, and the processor is further configured to send a charging signal to the charging coil to enable the charging coil to charge the electronic device.

20. An electronic device assembly, comprising:
an electronic device and a charging device;
wherein the charging device has a horizontal state and a vertical state and comprises:
a first housing defining a first receiving space;
a second housing rotatably connected with the first housing and configured to hold an electronic device;
a charging assembly received in the second housing and configured to charge the electronic device; and
a motor assembly received in the first receiving space and configured to drive the second housing to rotate relative to the first housing, wherein the second housing has a first end and a second end opposite the first end, the second end is farther away from the first housing than the first end when the charging device is in the vertical state, and wherein the motor assembly is connected with the second end;
in the horizontal state, the second housing is parallel to the first housing, and in the vertical state, the second housing is angled relative to the first housing; and
the electronic device comprises an induction coil and a battery, wherein the charging coil and the induction coil cooperate to charge the battery.
